(19) United States
(12) Patent Application Publication
(10) Pub. No.: US 2011/0316036 A1
(43) Pub. Date: Dec. 29, 2011

(54) LIGHT EMITTING DEVICE AND SEMICONDUCTOR WAFER

(75) Inventor: Chisato Furukawa, Kanagawa-ken (JP)

(73) Assignee: KABUSHIKI KAISHA TOSHIBA, Tokyo (JP)

(21) Appl. No.: 13/052,294

(22) Filed: Mar. 21, 2011

(30) Foreign Application Priority Data
Jun. 24, 2010 (JP) 2010-144107

(51) Int. Cl. H01L 33/36

(52) U.S. Cl. 257/99; 257/E33.062

(57) ABSTRACT

According to one embodiment, a light emitting device includes a substrate, a bonding layer, a plurality of protrusions, a first electrode, a translucent resin layer, and a first overcoat electrode. The bonding layer is provided on the substrate. The plurality of protrusions is provided on the bonding layer and includes a first conductivity type layer, a light emitting layer provided on the first conductivity type layer, and a second conductivity type layer provided on the light emitting layer. The first electrode is provided on the second conductivity type layer. The translucent resin layer is provided around the protrusions. The first overcoat electrode is provided on the translucent resin layer and connects the first electrodes respectively provided on the plurality of protrusions. The substrate, the translucent resin layer, and the first overcoat electrode each are exposed at a side surface of the light emitting device.

### CROSS-REFERENCE TO RELATED APPLICATIONS

This application is based upon and claims the benefit of priority from the prior Japanese Patent Application No. 2010-144107, filed on Jun. 24, 2010; the entire contents of which are incorporated herein by reference.

### FIELD

Embodiments described herein relate generally to a light emitting device and a semiconductor wafer.

### BACKGROUND

Light emitting devices used in headlamps, traffic signals, and lighting fixtures are required to produce high output power and high light extraction efficiency.

A translucent substrate can be used to extract emission light through the substrate to the outside. This facilitates improving the optical output and light extraction efficiency.

The characteristics such as wavelength and quantum efficiency can be determined by the internal structure of the stacked body including the light emitting layer. On the other hand, with the growing diversity of requirements for luminous intensity, chromaticity, and directional characteristics, the chip size and the layout of the light emitting region need to be adapted to various requirements. However, chip design for each application results in high-mix low-volume production and causes the problem of decreased productivity.

### BRIEF DESCRIPTION OF THE DRAWINGS

FIG. 1A is a schematic perspective view of a light emitting device according to a first embodiment, and FIG. 1B is a schematic cross-sectional view taken along line A-A;

FIGS. 2A to 2D are process sectional views of a method for manufacturing a light emitting device, where FIG. 2A is a schematic view of forming a first bonding layer, FIG. 2B is a schematic view of forming a second bonding layer, FIG. 2C is a schematic cross-sectional view of wafer bonding, and FIG. 2D is a schematic view of exposing a foundation layer;

FIGS. 3A and 3B are process sectional views of the method for manufacturing a light emitting device, where FIG. 3A is a schematic view of forming a semiconductor stacked body, and FIG. 3B is a schematic view of forming a first electrode;

FIGS. 4A to 4C are process sectional views of the manufacturing method of the first embodiment, where FIG. 4A is a schematic view of forming a photoresist pattern, FIG. 4B is a schematic view of selectively etching a semiconductor stacked body, and FIG. 4C is a schematic view of forming an overcoat electrode;

FIGS. 5A to 5C are schematic plan views of light emitting devices;

FIG. 6A is a schematic plan view of a light emitting apparatus, and FIG. 6B is a schematic cross-sectional view taken along line B-B;

FIG. 7A is a schematic perspective view of a light emitting device according to a second embodiment, and FIG. 7B is a schematic cross-sectional view taken along line C-C;

FIGS. 8A to 8D are process sectional views of a method for manufacturing the light emitting device of the second embodiment, where FIG. 8A is a schematic view of forming protrusions, FIG. 8B is a schematic view of forming a photoresist pattern, FIG. 8C is a schematic cross-sectional view of selectively etching a translucent resin layer, and FIG. 8D is a schematic view of forming a second electrode and an overcoat electrode; and

FIG. 9 is a schematic cross-sectional view of a flip-chip light emitting apparatus.

### DETAILED DESCRIPTION

In general, according to one embodiment, a light emitting device includes a substrate, a bonding layer, a plurality of protrusions, a first electrode, a translucent resin layer, and a first overcoat electrode. The bonding layer is provided on the substrate. The plurality of protrusions is provided on the bonding layer and includes a first conductivity type layer, a light emitting layer provided on the first conductivity type layer, and a second conductivity type layer provided on the light emitting layer. The first electrode is provided on the second conductivity type layer. The translucent resin layer is provided around the protrusions. The first overcoat electrode is provided on the translucent resin layer and connects the first electrodes respectively provided on the plurality of protrusions. The substrate, the translucent resin layer, and the first overcoat electrode each are exposed at a side surface of the light emitting device.

According to another embodiment, a light emitting device includes a substrate, a bonding layer, a foundation layer, a plurality of protrusions, a first electrode, a second electrode, a translucent resin layer, and a first overcoat electrode. The bonding layer is provided on the substrate. The foundation layer is provided on the bonding layer. The plurality of protrusions are provided on the foundation layer and include a first conductivity type layer, a light emitting layer provided on the first conductivity type layer, and a second conductivity type layer provided on the light emitting layer. The first electrode is provided on the second conductivity type layer. The second electrode is provided on the foundation layer between a first protrusion and a second protrusion of the plurality of protrusions. The translucent resin layer is provided around the protrusions and around the second electrode. The first overcoat electrode is provided on the translucent resin layer and connects the first electrodes respectively provided on the plurality of protrusions. The substrate, the translucent resin layer, and the first overcoat electrode each are exposed at a side surface of the light emitting device.

According to yet another embodiment, a semiconductor wafer includes a substrate, a bonding layer, a plurality of protrusions, a first electrode, a translucent resin layer, and a first overcoat electrode. The bonding layer is provided on the substrate. The plurality of protrusions are provided on the bonding layer and include a first conductivity type layer, a light emitting layer provided on the first conductivity type layer, and a second conductivity type layer provided on the light emitting layer. The first electrode is provided on the second conductivity type layer. The translucent resin layer is provided around the protrusions. The first overcoat electrode is provided on the translucent resin layer and connects the first electrodes respectively provided on the plurality of protrusions. A spacing region between the plurality of protrusions serves as a scribe region capable of being cut at a desired position.

Embodiments of the invention will now be described with reference to the drawings.

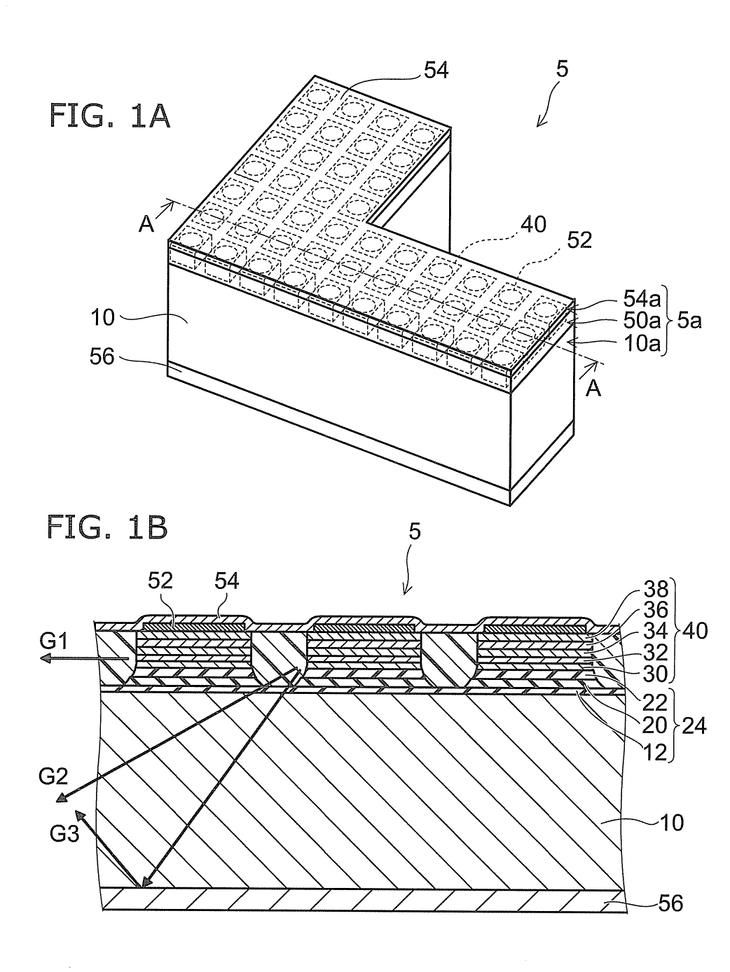

FIG. 1A is a schematic perspective view of a light emitting device according to a first embodiment. FIG. 1B is a schematic cross-sectional view taken along line A-A.

As shown in FIG. 1A, the light emitting device 5 includes a substrate 10, a bonding layer 24, a plurality of protrusions 40 provided on the bonding layer 24, a first electrode 52 provided on each protrusion 40, a translucent resin layer 50, a (first) overcoat electrode 54, and a second electrode 56.

The side surface 5a of the light emitting device 5 is a scribe surface at which the cross section 10a of the substrate 10, the cross section 50a of the translucent resin layer 50, and the cross section 54a of the overcoat electrode 54 are exposed. The protrusion 40 is not exposed at the side surface 5a. The spacing region between the plurality of protrusions 40 can be cut along a desired scribe line to form a chip including a desired number of protrusions 40 in a desired layout.

As shown in FIG. 1B, the protrusion 40 is made of a semiconductor stacked body including at least a first conductivity type layer 30, a light emitting layer 32 provided on the first conductivity type layer 30, and a second conductivity type layer 34 provided on the light emitting layer 32. Each protrusion 40 functions as an independent light emitting region spaced from the other protrusions 40. The first electrodes 52 respectively provided on the independent protrusions 40 are connected to each other by the overcoat electrode 54. Here, the semiconductor stacked body may further include a current spreading layer 36 provided on the second conductivity type layer 34 and having the second conductivity type, and a contact layer 38 provided on the current spreading layer 36 and including a second conductivity type layer.

The protrusion 40 is shaped like e.g. a rectangle or square measuring 10 to 100 μm on a side. The first electrode 52 is shaped like e.g. a circle or square smaller than the protrusion 40.

The translucent resin layer 50 is provided around each protrusion 40. The overcoat electrode 54 connecting the first electrodes 52 is provided on the translucent resin layer 50. The translucent resin layer 50 can be made of e.g. PMMA (polymethyl methacrylate) or PI (polyimide). The translucent resin layer 50 thus provided can passivate the cut side surface of the semiconductor stacked body.

In FIG. 1B, the substrate 10 is conductive. The second electrode 56 is provided on the surface of the substrate 10 opposite from the surface provided with the bonding layer 24.

Light G1 emitted from the side surface of the light emitting layer 32 can be directly extracted from the lateral side. The substrate 10 can be translucent. Then, the light emitted downward includes light G2 emitted from the side surface 10a of the substrate 10 and light G3 reflected by the second electrode 56 and then emitted from the side surface 10a of the substrate 10. For instance, the thickness of the protrusion 40 can be set to 5-10 μm. The spacing distance between the side surfaces of the protrusions 40 can be set to 5 to 20 μm. The thickness of the substrate 10 can be set to 70 to 400 μm. In such a structure, the light transmitted through the substrate 10 can be efficiently extracted from the side surface 10a of the substrate 10. However, the upper surface of the semiconductor substrate is provided with the first electrode 52 and the overcoat electrode 54. Hence, the amount of light extraction therefrom is small.

More preferably, the substrate 10 is made of a material being translucent to the emission light from the light emitting layer 32. Such a material can be e.g. GaP, GaN, or SiC.

The light emitting layer 32 can be made of such materials as Inₓ(Al_{y}Ga_{1-y})₁₋ₓP (0≦x≦1, 0≦y≦1), AlₓGa₁₋ₓAs (0≦x≦1), and InₓGa_{y}Al_{1-x-y}N (0≦x≦1, 0≦y≦1, x+y≦1). These materials may contain elements serving as acceptors or donors.

In the case where the substrate 10 is made of GaP and the stacked body is made of Inₓ(Al_{y}Ga_{1-y})₁₋ₓP (0≦z≦1, 0≦y≦1), light in the wavelength range of 500 to 700 nm can be emitted.

The light emitting device 5 including a number n of protrusions 40 can achieve generally n times the luminous intensity (optical output) of one protrusion 40. That is, in response to the requirement for luminous intensity, the number n of protrusions 40 can be determined, and the chip size can be freely changed. Furthermore, in response to the requirement for directional characteristics, the chip shape can be determined. Then, desired directional characteristics can be achieved.

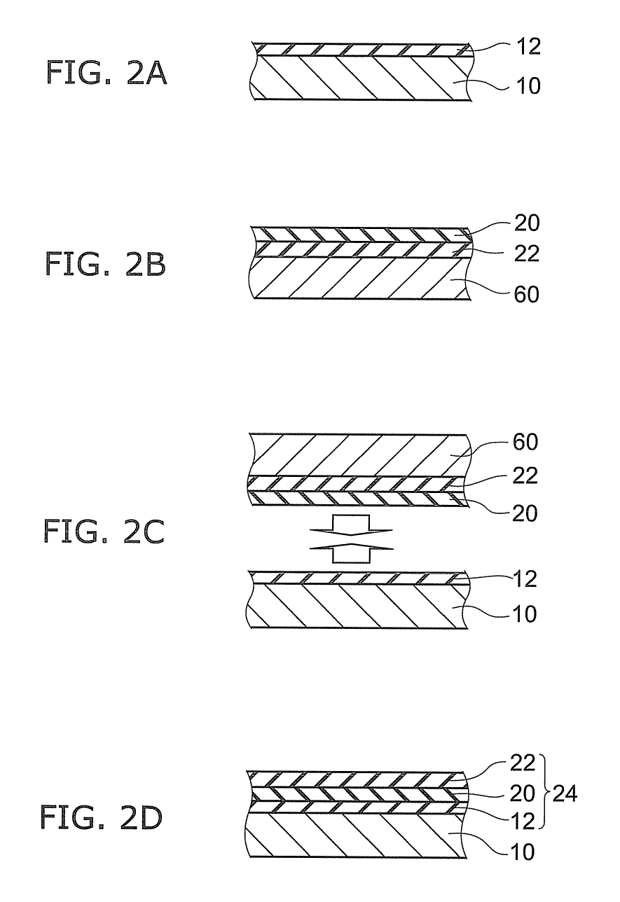

FIGS. 2A to 2D are process sectional views of a method for manufacturing a light emitting device. More specifically, FIG. 2A is a schematic view of forming a first bonding layer. FIG. 2B is a schematic view of forming a second bonding layer. FIG. 2C is a schematic view of wafer bonding. FIG. 2D is a schematic view of removing the crystal growth substrate.

As shown in FIG. 2A, on a conductive substrate 10 made of GaP, a first bonding layer 12 made of p-type GaP is formed.

On the other hand, as shown in FIG. 2B, on a substrate 60 made of GaAs, a film 22 for lattice matching and a second bonding layer 20 are formed.

Subsequently, as shown in FIG. 2C, in the wafer state, the first bonding layer 12 and the second bonding layer 20 are brought into contact, and bonded together by heating under pressurization. Furthermore, the substrate 60 is removed by e.g. polishing or etching. Thus, as shown in FIG. 2D, a bonding layer 24 including the film 22 on the surface is formed on the substrate 10. This facilitates lattice matching with the crystal growth layer to be formed subsequently.

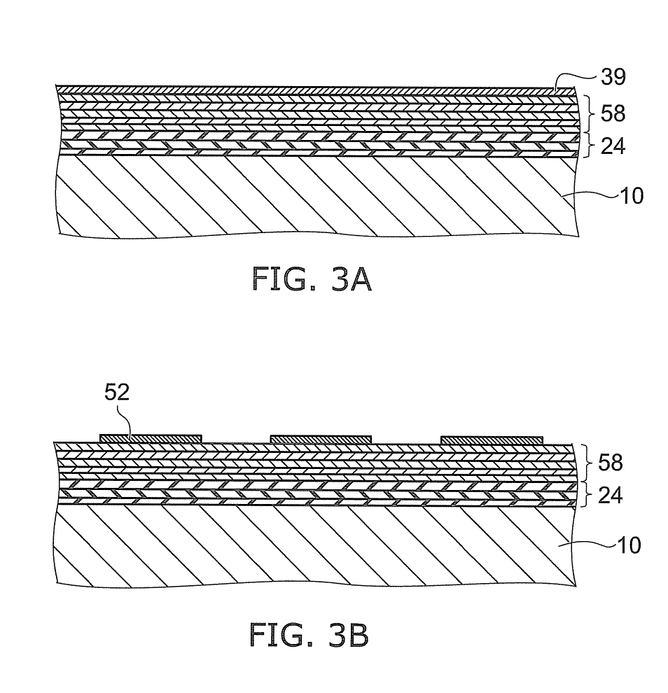

FIGS. 3A and 3B are process sectional views of the method for manufacturing a light emitting device. More specifically, FIG. 3A is a schematic view of forming a semiconductor stacked body. FIG. 3B is a schematic view of forming a first electrode.

As shown in FIG. 3A, a semiconductor stacked body 58 is formed on the bonding layer 24 by the MOCVD (metal organic chemical vapor deposition) method or MBE (molecular beam epitaxy) method. The semiconductor stacked body 58 includes, from the bonding layer 24 side, a first conductivity type layer 30 including a cladding layer (thickness 0.6 μm) made of p-type In_{0.5}Al_{0.5}P, a light emitting layer 32, a second conductivity type layer 34 including a cladding layer (thickness 0.6 μm) made of In_{0.5}Al_{0.5}P, a current spreading layer (thickness 2 μm) 36 made of In_{0.5}(Al_{0.7}Ga_{0.3})_{0.5}P, and a contact layer 38 made of n-type Ga_{0.5}Al_{0.5}As in this order. Furthermore, a dummy layer 39 may be provided on the semiconductor stacked body 58. The light emitting layer 32 can have an MQW (multi-quantum well) structure, for instance. This facilitates controlling the emission wavelength and reducing the operating current.

The thickness and composition of each layer of the semiconductor stacked body 58 are not limited to the foregoing. Furthermore, the conductivity type of the translucent substrate 10 and the semiconductor stacked body 58 may be reversed. Furthermore, as an alternative method, a stacked body including a light emitting layer 32 can be crystal grown on a substrate 60 made of e.g. GaAs, and wafer-bonded to a substrate 10. Then, the substrate 60 can be removed. This simplifies the process.

Subsequently, as shown in FIG. 3B, the dummy layer 39 is removed. Then, first electrodes 52 spaced from each other are formed on the semiconductor stacked body 58.

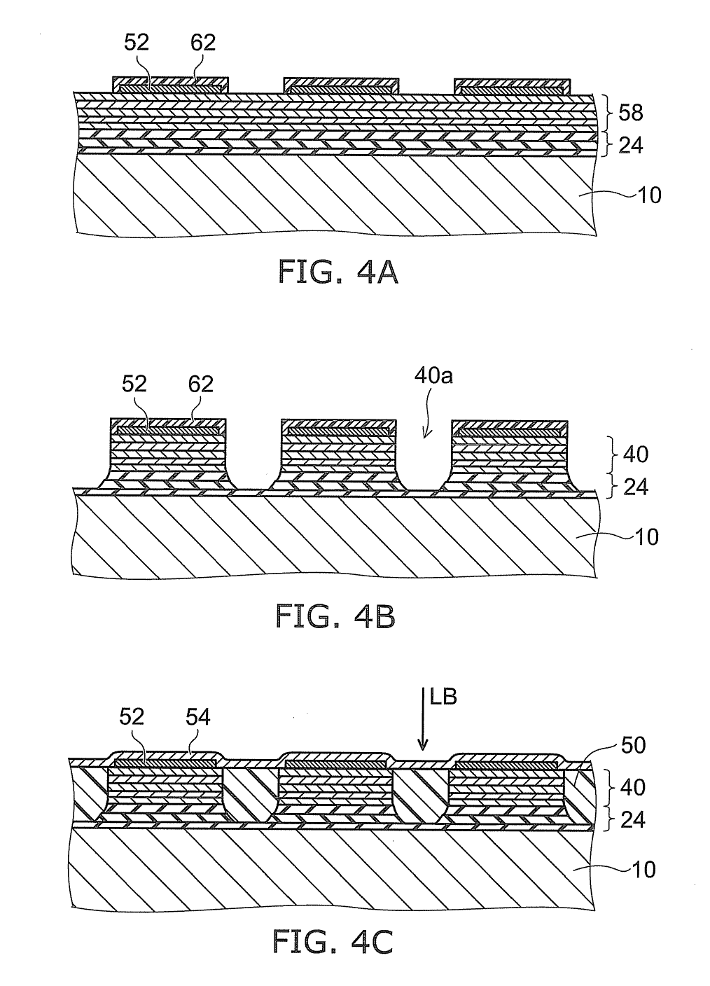

FIGS. 4A to 4C are process sectional views of the manufacturing method of the first embodiment. More specifically, FIG. 4A is a schematic view of forming a photoresist pattern. FIG. 4B is a schematic view of forming protrusions. FIG. 4C is a schematic view of forming an overcoat electrode.

As shown in FIG. 4A, a pattern of a photoresist film 62 is formed on the region where a protrusion 40 is to be formed. Here, preferably, the pattern of the photoresist film 62 is made larger than the first electrode 52.

As shown in FIG. 4B, part of the semiconductor stacked body 58 is removed by etching to form protrusions 40 each shaped like a mesa, for instance. Here, the protrusions 40 can be independently driven as a plurality of light emitting regions by separation down to at least the contact layer 38, the current spreading layer 36, and the second conductivity type layer 34. Separation down to the light emitting layer 32 and the first conductivity type layer 30 is more preferable. Furthermore, separation may be performed down to all or part of the bonding layer 24. Subsequently, the photoresist film 62 is removed.

A translucent resin layer 50 made of e.g. PMMA is applied until the first electrode 52 is covered and the surface is flattened while filling the spacing region 40a between the protrusions 40. Furthermore, the translucent resin layer 50 is etched away by the CDE (chemical dry etching) method until the surface of the first electrode 52 is exposed. Subsequently, as shown in FIG. 4C, an overcoat electrode 54 is formed so as to cover the spaced first electrodes 52. The thickness of the overcoat electrode 54 is set so that scribing is easy and a generally equal voltage is applied to the plurality of protrusions 40.

Subsequently, the back surface of the substrate 10 is thinned by polishing, and a second electrode 56 is formed thereon. Thus, a semiconductor wafer is completed.

Such a semiconductor wafer has a structure in which a plurality of light emitting regions made of the protrusions 40 are electrically parallel connected between the overcoat electrode 54 and the second electrode 56 on the back surface of the substrate 10. The protrusions 40 are spaced from each other. Hence, the semiconductor wafer can be divided by scribing so as to include a desired number of protrusions 40.

Here, the semiconductor wafer is diced by the laser dicing method. In the laser dicing method, the semiconductor wafer is irradiated with a laser beam LB scanned along the scribe line at a desired position. Alternatively, the semiconductor wafer may be cut with a water jet saw. Thus, a chip having a desired shape and size can be separated. Here, the overcoat electrode 54 is scribed above the translucent resin layer 50, and the first electrodes 52 in the chip are commonly connected by the overcoat electrode 54.

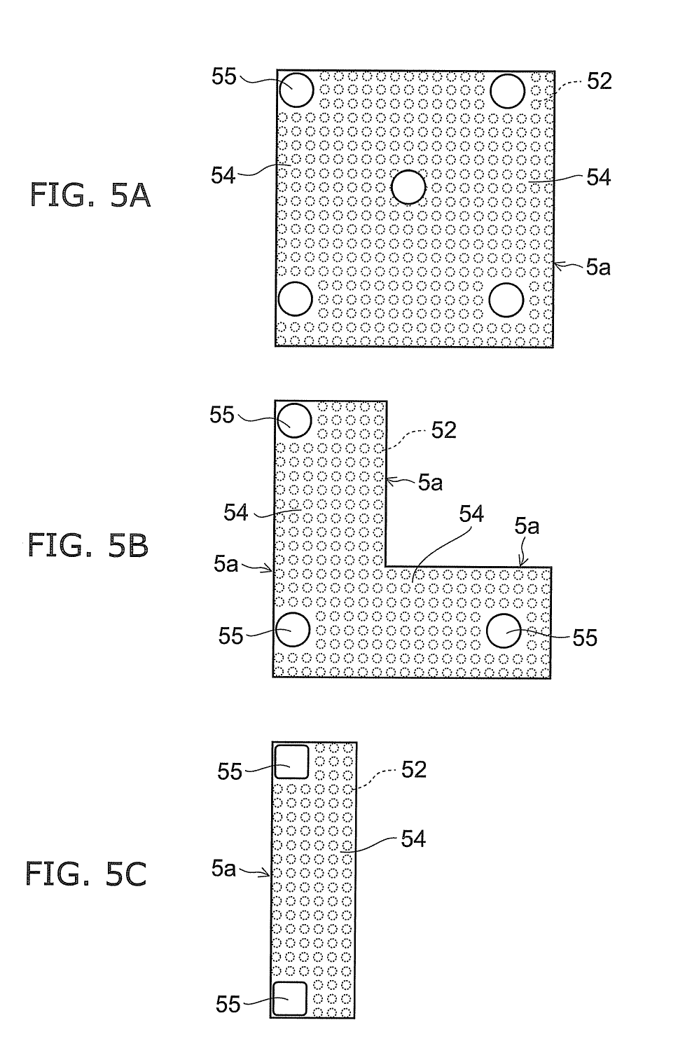

FIGS. 5A to 5C are schematic plan views of light emitting devices.

FIG. 5A shows a light emitting device scribed in a rectangle. FIG. 5B shows a light emitting device scribed in an angled shape. Such a shape can be easily scribed by scanning a laser beam, for instance. FIG. 5C shows a light emitting device scribed in a smaller rectangle adapted for purposes with low luminous intensity. Thus, the spacing region 40a between the protrusions 40 can be used as a scribe region depending on the desired planar shape of the chip.

As shown in FIGS. 5A to 5C, a pad electrode 55 having a prescribed thickness can be provided on the overcoat electrode 54 by using the lift-off method, for instance. Advantageously, this can increase the wire bonding strength and the flip-chip bonding strength.

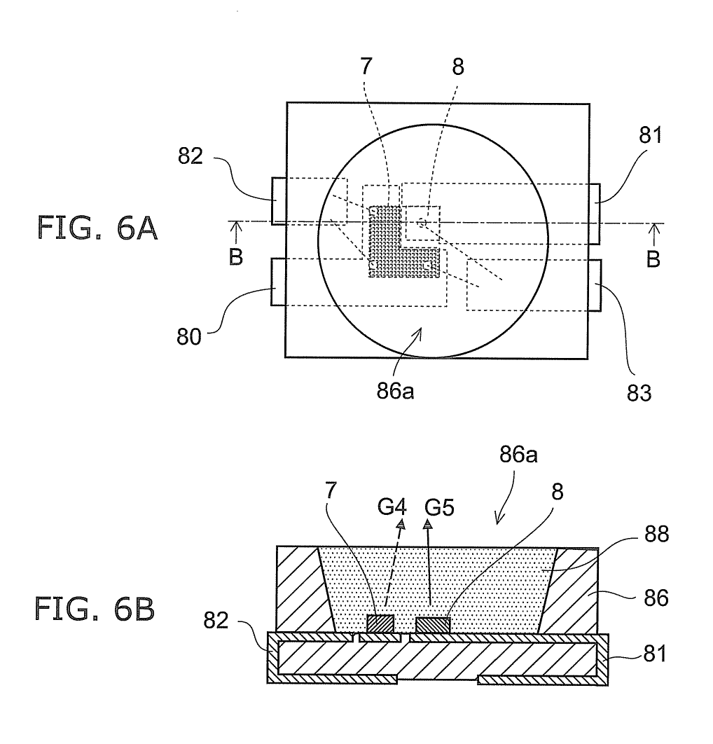

FIG. 6A is a schematic plan view of a light emitting apparatus. FIG. 6B is a schematic cross-sectional view taken along line B-B.

It is assumed that the angled light emitting device 7 shown in FIG. 5B emits green light indicated by the dashed line G4. It is also assumed that the light emitting device 8 emits red light indicated by the solid line G5. In an SMD (surface mounted device) light emitting apparatus shown in FIGS. 6A and 6B, for instance, leads 80 and 81 serve as a cathode, and leads 82 and 83 serve as an anode. By changing the size or shape of the light emitting device 7, the chromaticity of the mixed light of the dashed line G4 and the solid line G5 can be changed from green to red. Thus, a desired chromaticity is easily obtained. Furthermore, by increasing the size of the light emitting devices 7 and 8, the luminous intensity of the mixed light can be increased.

Here, the refractive index of the translucent resin layer 50 can be set between the refractive index of the protrusion 40 and the refractive index of the sealing resin made of silicone or epoxy covering the chip. This can further increase the light extraction efficiency.

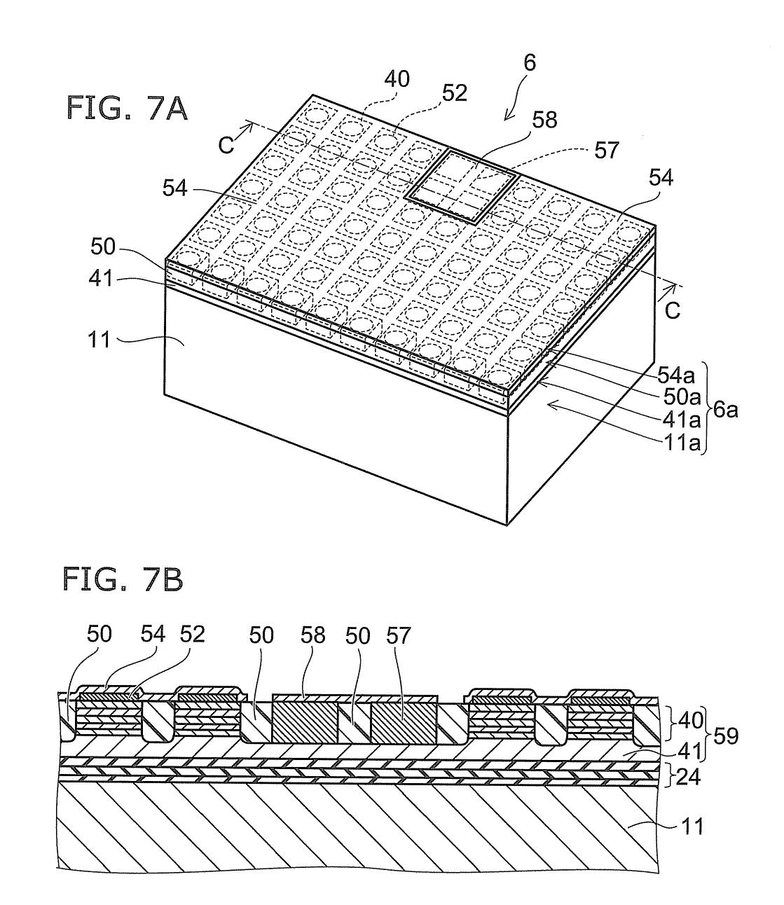

FIG. 7A is a schematic perspective view of a light emitting device according to a second embodiment. FIG. 7B is a schematic cross-sectional view taken along line C-C.

The light emitting device 6 includes a substrate 11, a bonding layer 24, a semiconductor stacked body 59, a first electrode 52, a translucent resin layer 50, an overcoat electrode 54, a second electrode 57, and a (second) overcoat electrode 58.

As shown in FIG. 7A, the side surface 6a of the light emitting device 6 is a scribe surface at which the cross section 11a of the substrate 11, the cross section 41a of the foundation layer 41, the cross section 50a of the translucent resin layer 50, and the cross section 54a of the overcoat electrode 54 are exposed. The protrusion 40 is not exposed at the side surface 6a.

As shown in FIG. 7B, upon cutting the overcoat electrode 54, a plurality of protrusions 40 can be independently driven. That is, a chip including a desired number of protrusions 40 in a desired layout can be scribed.

The semiconductor stacked body 59 is provided on the bonding layer 24. The semiconductor stacked body 59 includes a foundation layer 41 having the first conductivity type and a plurality of protrusions 40 provided on the foundation layer 41. The substrate 11 is a translucent substrate made of e.g. sapphire or GaP.

The foundation layer 41 having the first conductivity type is crystal grown on a film 22 constituting the bonding layer 24. Further thereon, a protrusion 40 including a light emitting layer 32 is crystal grown. The second electrode 57 is provided on the upper surface or stepped surface of the foundation layer 41 so as to be interposed between the first and second protrusion 40.

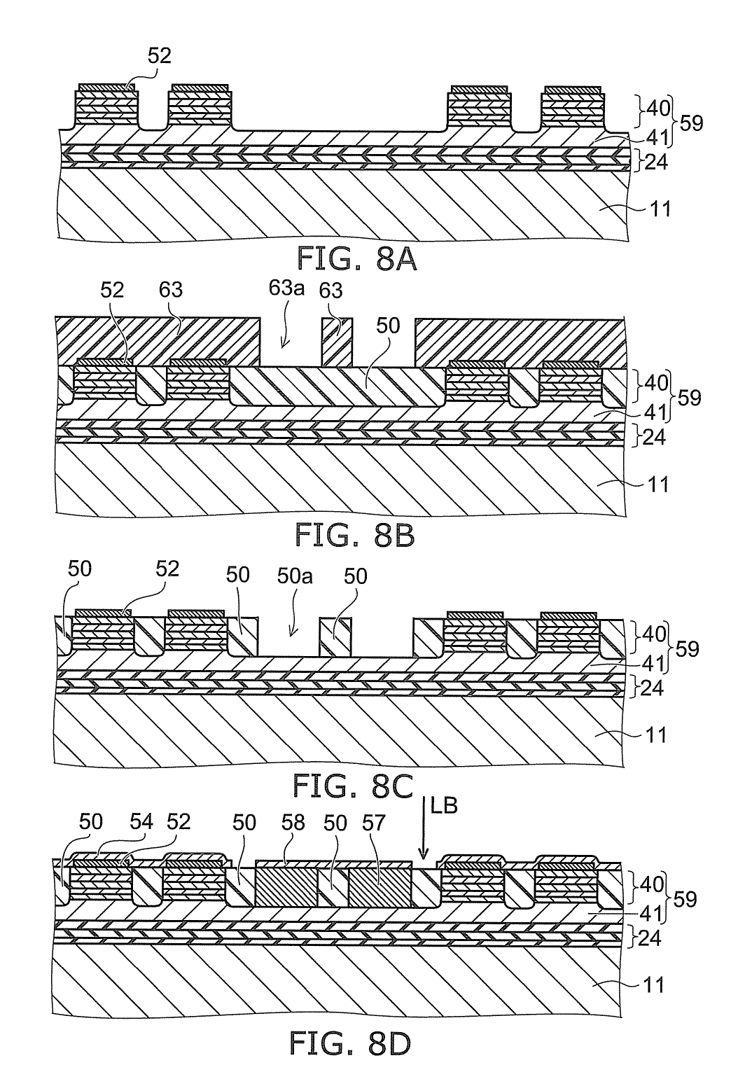

FIGS. 8A to 8D are process sectional views of a method for manufacturing a light emitting device of the second embodiment. More specifically, FIG. 8A is a schematic view of forming protrusions. FIG. 8B is a schematic view of forming a photoresist pattern. FIG. 8C is a schematic view of selectively etching the translucent resin layer. FIG. 8D is a schematic view of forming a second electrode and an overcoat electrode.

As shown in FIG. 8A, a prescribed region for forming a second electrode 57 is removed in the process of dividing the semiconductor stacked body 59 into a plurality of protrusions 40. Here, the bottom surface around the protrusion 40 may be any one of the foundation layer 41, the bonding layer 24, and the substrate 11. As shown in FIG. 8B, a photoresist film 63 is patterned to form an opening 63a in the prescribed region. Subsequently, as shown in FIG. 8C, the translucent resin layer 50 is removed by etching to provide an opening 50a.

On the bottom surface around the protrusion 40, a second electrode 57 is formed by evaporation, plating, or a combination thereof. Here, preferably, the surface of the second electrode 57 is made generally flush with the first electrode 52. Subsequently, as shown in FIG. 8D, the photoresist film 63 is removed. Then, an overcoat electrode 54 connecting the first electrodes 52, and an overcoat electrode 58 connecting the second electrodes 57 are formed by using the lift-off method, for instance. Subsequently, the semiconductor wafer is scribed by irradiation with a laser beam LB along a desired scribe line. Here, the scribe line can pass through not only the spacing region between the protrusions 40, but also the spacing region between the second electrodes 57 and the spacing region between the protrusion 40 and the second electrode 57.

The planar size of one second electrode 57 does not need to be equal to the planar size of one protrusion 40. However, if they are generally equal, the semiconductor wafer can be cut at a desired position in the spacing region between the second electrodes 57 connected by the overcoat electrode 58. Hence, the scribe line can be freely designed throughout the wafer. Here, the area of the second electrode 57 can be decreased as long as the contact resistance of the foundation layer 41 and the second electrode 57 can be kept low. This facilitates expanding the area of the light emitting region and further increasing the optical output.

The substrate 11 can be made of a material having a high Mohs hardness such as sapphire. Then, even if its thickness is set to e.g. 100 μm or less, the mechanical strength including shear strength can be easily kept high. This facilitates reducing the chip thickness, and the SMD (surface mounted device) light emitting apparatus can be thinned.

The stacked body can be made of InₓGa_{y}Al_{1-x-y}N (0≦x≦1, 0≦y≦1, x+y≦1). Then, light in the wavelength range of 410-500 nm can be emitted.

Furthermore, the substrate 11 may be a conductive substrate made of e.g. GaP. In this case, the second electrode may be provided on the back surface side of the substrate 11 or between the protrusions 40.

In the case where the substrate 11 is insulative, the chip is scribed with a desired number of protrusions 40 and a desired shape so as to include at least one protrusion 40 and at least one second electrode 57.

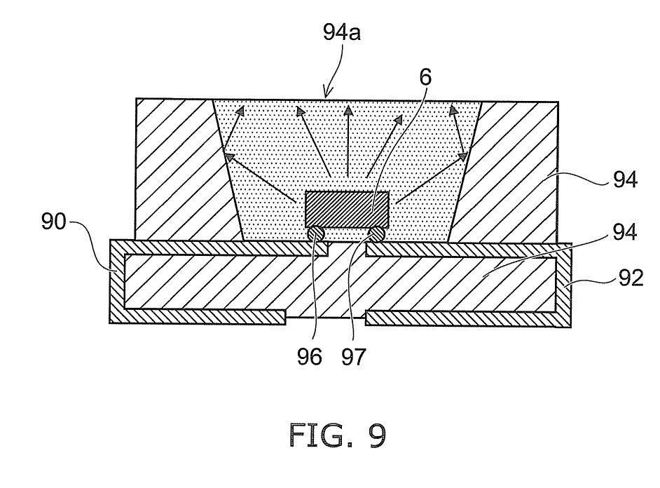

FIG. 9 is a schematic cross-sectional view of a flip-chip light emitting apparatus.

A first lead 90 and a second lead 92 are embedded in a molded body 94 made of resin, and outer leads are drawn out therefrom. The molded body 94 includes a recess 94a. The first lead 90 and the second lead 92 are exposed at the bottom surface of the recess 94a. The overcoat electrode 54 of the light emitting device 6 having the structure of FIGS. 7A and 7B is bonded to the first lead 90 with a metal bump 96. The overcoat electrode 58 is bonded to the second lead 92 with a metal bump 97. Thus, a light emitting apparatus having the flip-chip structure can be obtained. The back surface of the light emitting device 6 can be formed from a translucent substrate 11. Then, light is not blocked by the back surface electrode, and high light extraction efficiency can be achieved.

The first and second embodiments provide a light emitting device and a semiconductor wafer in which a desired chip size and chip shape are easily achieved. This facilitates achieving a light emitting apparatus having desired luminous intensity, chromaticity, and directional characteristics, and can be widely used in headlamps, traffic signals, and lighting fixtures. Furthermore, a semiconductor wafer having the same specifications can be used to supply chips responding to various required characteristics. Thus, the productivity of the light emitting apparatus can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A light emitting device comprising:
a substrate;
a bonding layer provided on the substrate;
a plurality of protrusions provided on the bonding layer and including a first conductivity type layer, a light emitting layer provided on the first conductivity type layer, and a second conductivity type layer provided on the light emitting layer;
a first electrode provided on the second conductivity type layer;
a translucent resin layer provided around the protrusions; and
a first overcoat electrode provided on the translucent resin layer and connecting the first electrodes respectively provided on the plurality of protrusions,
the substrate, the translucent resin layer, and the first overcoat electrode each being exposed at a side surface of the light emitting device.

2. The device according to claim 1, wherein the substrate is conductive and electrically connected to the first conductivity type layer.

3. The device according to claim 1, wherein the bonding layer is further exposed at the side surface of the light emitting device.

4. The device according to claim 1, further comprising:
a second electrode provided on a back surface of the substrate.

5. The device according to claim 1, wherein the plurality of protrusions have an identical shape as viewed from above.

6. The device according to claim 1, wherein one corner of the light emitting device has 270 degrees and remaining corners have 90 degrees as viewed from above.

7. A light emitting device comprising:
a substrate;
a bonding layer provided on the substrate;
a foundation layer provided on the bonding layer;
a plurality of protrusions provided on the foundation layer and including a first conductivity type layer, a light emitting layer provided on the first conductivity type layer, and a second conductivity type layer provided on the light emitting layer;
a first electrode provided on the second conductivity type layer;
a second electrode provided on the foundation layer between a first protrusion and a second protrusion of the plurality of protrusions;
a translucent resin layer provided around the protrusions and around the second electrode; and
a first overcoat electrode provided on the translucent resin layer and connecting the first electrodes respectively provided on the plurality of protrusions,
the substrate, the translucent resin layer, and the first overcoat electrode each being exposed at a side surface of the light emitting device.

8. The device according to claim 7, wherein the substrate is conductive and electrically connected to the first conductivity type layer.

9. The device according to claim 7, wherein the substrate is insulation.

10. The device according to claim 7, wherein the bonding layer is further exposed at the side surface of the light emitting device.

11. The device according to claim 7, wherein the second electrode includes a plurality of regions.

12. The device according to claim 11, further comprising:
a second overcoat electrode connecting the plurality of regions of the second electrode.

13. The device according to claim 12, wherein the second overcoat electrode is further exposed at the side surface of the light emitting device.

14. The device according to claim 7, wherein the plurality of protrusions have an identical shape as viewed from above.

15. The device according to claim 7, wherein the plurality of protrusions and the plurality of regions of the second electrode have an identical shape as viewed from above.

16. The device according to claim 7, wherein one corner of the light emitting device has 270 degrees and remaining corners have 90 degrees as viewed from above.

17. A semiconductor wafer comprising:
a substrate;
a bonding layer provided on the substrate;
a plurality of protrusions provided on the bonding layer and including a first conductivity type layer, a light emitting layer provided on the first conductivity type layer, and a second conductivity type layer provided on the light emitting layer;
a first electrode provided on the second conductivity type layer;
a translucent resin layer provided around the protrusions; and
a first overcoat electrode provided on the translucent resin layer and connecting the first electrodes respectively provided on the plurality of protrusions,
a spacing region between the plurality of protrusions serving as a scribe region capable of being cut at a desired position.

18. The wafer according to claim 17, further comprising:
a foundation layer provided between the bonding layer and the protrusion and including a first conductivity type semiconductor; and
a second electrode provided on the foundation layer between a first protrusion and a second protrusion of the plurality of protrusions and surrounded by the translucent resin layer.

19. The wafer according to claim 18, wherein the second electrode includes a plurality of regions.

20. The wafer according to claim 19, further comprising:
a second overcoat electrode connecting the plurality of regions of the second electrode.
